(19) United States
(12) Patent Application Publication
(10) Pub. No.: US 2010/0328870 A1
(43) Pub. Date: Dec. 30, 2010

(54) INFORMATION PROCESSING APPARATUS

(75) Inventors: Kazuhiro Nakamura, Hachioji-shi (JP); Hiroshi Aiba, Oume-shi (JP); Koichiro Takeguchi, Hachioji-shi (JP)

Correspondence Address: KNOBBE MARTENS OLSON & BEAR LLP, 2040 MAIN STREET, FOURTEENTH FLOOR, IRVINE, CA, 92614, US

(73) Assignee: KABUSHIKI KAISHA TOSHIBA, Tokyo (JP)

(21) Appl. No.: 12/792,657

(22) Filed: Jun. 2, 2010

(30) Foreign Application Priority Data
Jun. 30, 2009 (JP) 2009-155258

(51) Int. Cl. H05K 7/00

(52) U.S. Cl. 361/679.4

(57) ABSTRACT

An information processing apparatus includes: a wireless communication unit configured to perform wireless communication with counterpart devices; a housing configured to include the wireless communication unit, the housing being formed with an opening for exposing the wireless communication unit; a lid member configured to be movable between an opened position for opening the opening and a closing position for closing the opening; and an input device configured to receive an input and outputs an operation signal in accordance with the input, the input device being provided on the housing, wherein the input device includes the lid member.

### CROSS REFERENCE TO RELATED APPLICATION(S)

The present disclosure relates to the subject matters contained in Japanese Patent Application No. 2009-155258 filed on Jun. 30, 2009, which are incorporated herein by reference in its entirety.

### FIELD

The present invention relates to an information processing apparatus that has a non-contact type communication device.

### BACKGROUND

various information processing apparatuses that include a non-contact type communication device have been proposed. For example, a card installation terminal disclosed in JP-A-2008-305067 includes: a terminal; a card storage unit that is disposed in the surface portion of the terminal main body in a concaved shape and stores a predetermined shaped card therein; an input device that is disposed on the surface portion of the terminal main body; a card information reading unit that reads out card information recorded in a card when the card is stored in the card storage unit as a non-contact type communication device; a display unit main body that is configured as a body separated from the terminal main body; and a slide mechanism that allows the display unit main body to slide on the surface portion of the terminal main body.

When the card stored in the card storage unit is covered and the display unit main body is slid to the position for exposing the input device by the slide mechanism in this card installation terminal, the card is configured to be fixed to the card storage unit by the slid display unit main body. Thus, according to this card installation terminal, the card is prevented from being dislodged by reliably fixing the card to the card installation terminal, whereby the usability can be improved.

The configuration disclosed in the publication, JP-A-2008-305067, is used by a terminal used for inputting a password in a case where payment is made by using a card. In other words, the terminal is given and received between a store clerk and a purchaser. Accordingly, in order to prevent the card from dislodging, the card is fixed to the card installation terminal.

On the other hand, it is difficult to consider applying the above-described fixing configuration to a general information processing apparatus such as a notebook personal computer (hereinafter, referred to as a notebook PC). First, commonly, the notebook PC is not used by a plurality of persons. In addition, the notebook PC can be considered to perform non-contact type communication with various types of apparatuses (a cellular phone, a PDA (Personal Digital Assistant), and the like), and accordingly, it is not appropriate to arrange a configuration that is used for storing and fixing a specific apparatus.

In addition, in the information processing apparatus such as a notebook PC that includes a housing formed by a metallic member, wireless communication between the inside and the outside of the housing is blocked by metal in a case where a non-contact type communication device is disposed inside the housing. Accordingly, it is difficult to use the Therefore, in the information processing apparatus of such a type, installation of the non-contact type communication device is abandoned or at least a portion of the housing that corresponds to the non-contact type communication device needs to be formed by a non-metallic member such as a plastic member. However, in a case where a non-metallic member is used in a portion of the housing, the external appearance of the information processing apparatus is spoiled, and the impact strength cannot be easily ensured. In addition, a non-metallic member cannot be easily used in a portion of the housing such as a portion in which a touchpad or a keyboard is disposed or the like. Thus, the range of methods for using non-metallic member in a portion of the housing is limited.

### BRIEF DESCRIPTION OF THE DRAWINGS

A general configuration that implements the various feature of the invention will be described with reference to the drawings. The drawings and the associated descriptions are provided to illustrate embodiments of the invention and not to limit the scope of the invention.

FIG. 1 is a schematic external view showing an information processing apparatus according to an embodiment of the present invention.

FIG. 2 is a schematic block diagram showing an example of the internal configuration of a notebook PC.

FIG. 3 is an external view showing an example of the notebook PC in which a wireless communication unit is disposed on the lower side of the touch unit.

FIG. 4 is an explanatory diagram showing an example of the appearance of the exposed wireless communication unit by opening the touch unit.

FIG. 5 is an explanatory diagram showing an example of the appearance of approaching of a counterpart wireless communication unit to the exposed wireless communication unit so as to be able to communicate with each other.

FIG. 6A is a front perspective view of a cellular phone in a state being folded, and FIG. 6B is a rear perspective view.

FIG. 7 is an external view showing an example of the notebook PC in which the wireless communication unit is disposed on the lower side of a keyboard.

FIG. 8 is an explanatory diagram showing an example of the appearance of exposure of the wireless communication unit by opening the keyboard.

### DETAILED DESCRIPTION OF THE EMBODIMENTS

An information processing apparatus according to an embodiment of the present invention will be described with reference to the accompanying drawings.

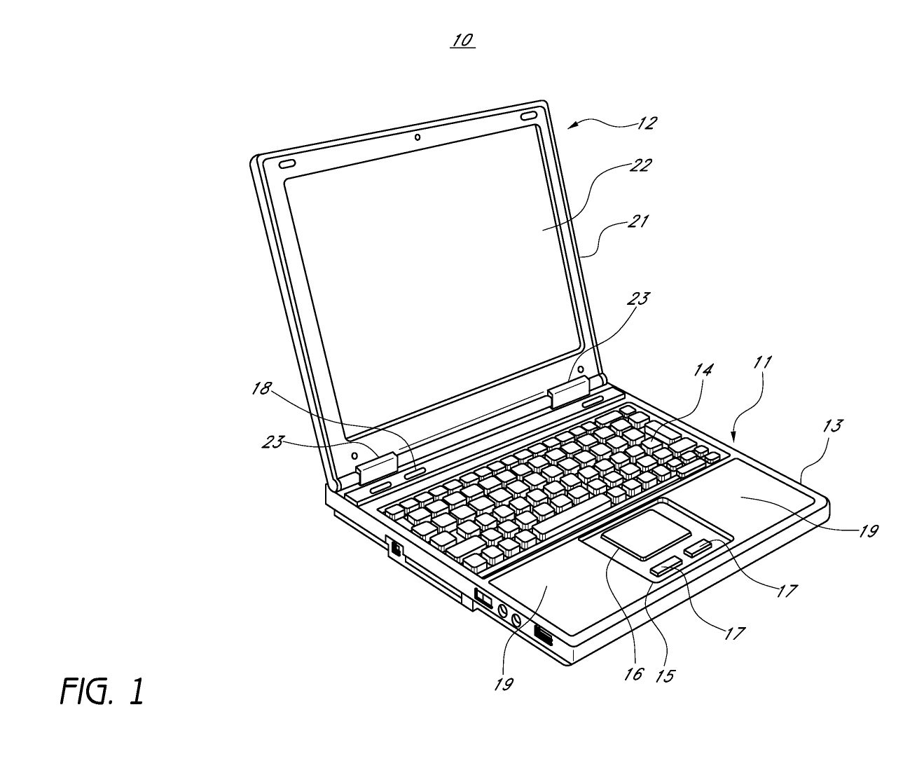

FIG. 1 is a schematic external view showing an information processing apparatus according to an embodiment of the present invention.

The present invention can be applied to various information processing apparatuses in which a housing configured by a metal member is included and a non-contact type communication device is disposed inside the housing. In this embodiment, as the information processing apparatus according to the present invention, an example of a case where a notebook personal computer (notebook PC) is used is represented.

The notebook PC 10 includes a device main body 11 and a display unit 12 as a display device.

The device main body 11 has a thin box-shaped housing 13. This housing 13, for example, is configured by a metal member formed of a magnesium alloy, aluminum, or the like. In the center portion of the top face of the housing 13, a keyboard 14 as an input device is disposed. On the front side of the top face of the housing 13, a palm rest 19 is formed. In an approximate center portion of the palm rest 19, a touchpad unit 15 as an input device for inputting an operation input signal, which corresponds to the user's operation, to the device main body 11 is disposed. The touchpad unit 15 has a pad 16 and buttons 17. In addition, on the inner side of the top face of the housing 13 of the device main body 11, a power button 18 that is used for turning the power of the notebook PC 10 on or off is disposed.

The display unit 12 as a display device includes a thin box-shaped housing 21. In this housing 21, an LCD (Liquid Crystal Display) 22 as the display unit is built in. The display unit 12 is connected to the device main body 11 through a hinge (hinge) 23 that supports the display unit 12 so as to be freely opened or closed with respect to the device main body 11.

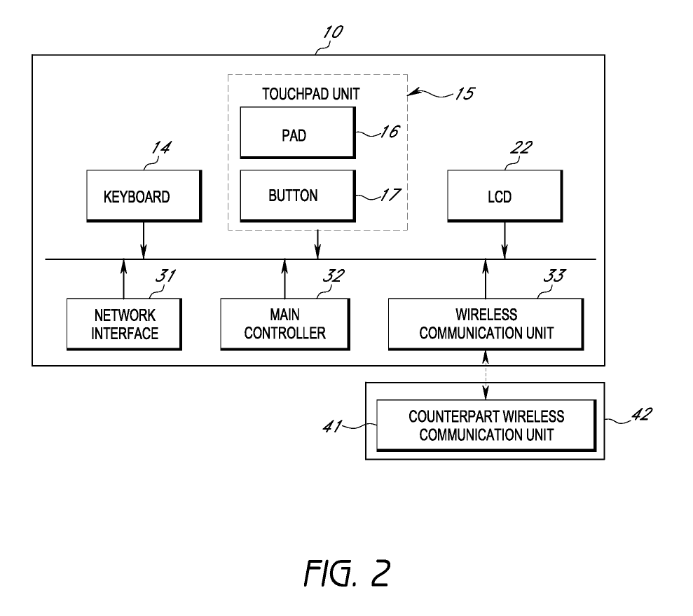

FIG. 2 is a schematic block diagram showing an example of the internal configuration of the notebook PC 10.

The notebook PC 10 includes the keyboard 14, the touchpad unit 15, the LCD 22 as the display unit, a network interface 31, a main controller 32, and a non-contact type wireless communication unit 33.

The keyboard 14 and the touchpad unit 15 as input devices output operation input signals corresponding to the user's operations to the main controller 32.

The LCD 22 as the display unit displays various types of information in accordance with control of the main controller 32. For example, when the wireless communication unit 33 and a counterpart wireless communication unit 41 are connected to each other in a wireless manner so as to be wirelessly communicatable, the LCD 22 displays information on the data that is transmitted and received through the wireless communication.

The network interface 31 implements various information communication protocols based on the form of the network. The network interface 31 connects the notebook PC and the above-described other devices together in accordance with the various protocols. To the connection, electrical connection through an electronic network or the like can be applied. Here, the electronic network represents the overall information communication network using the above-described communication technology and includes a telephone communication circuit network, an optical fiber communication network, a cable communication network, a satellite communication network, and the like, in addition to a wireless or wired LAN (local area network) and the internet network.

The main controller 32 is configured by a CPU, memory media such as a RAM and a ROM, and the like. The main controller 32 controls the processing operation of the notebook PC 10 in accordance with a program stored in the memory media.

The CPU of the main controller 32 loads an application program that is stored in the memory medium such as the ROM and data that is needed for executing the program into the RAM. Then, the CPU of the main controller 32 allows the wireless communication unit 33 to serve as a reader or a write in accordance with the program, so that data can be transmitted and received between the wireless communication unit 33 and other wireless communication units 41 in a wireless manner.

The RAM of the main controller 32 provides a work area that is used for temporarily storing a program executed by the CPU and data.

The memory media of the main controller 32 such as the ROM store a start-up program and an application program of the notebook PC 10 and various types of data needed for executing the programs therein.

The memory medium such as the ROM is configured to include a recording medium such as a magnetic or optical recording medium, a semiconductor memory, or the like that can be read by the CPU. A part or the whole of the program and the data that are stored in the memory medium may be configured to be downloaded through the electronic network.

The wireless communication unit 33 of the non-contact type is configured by a wireless communication device of the non-contact type such as so-called an adhesion type, a proximity type, or a neighborhood type and is disposed inside the housing 13. In this embodiment, an example of a case where the wireless communication unit 33 is configured by a non-contact type wireless communication device of the proximity type and is controlled by the main controller 32 so as to implement the functions as a reader and a writer is represented. In such a case, when an electronic apparatus having a non-contact type wireless communication device (hereinafter, referred to as a counterpart wireless communication unit 41) of the proximity type such as a cellular phone 42 approaches the wireless communication unit 33, the wireless communication unit 33 can communicate with the counterpart wireless communication unit 41 in a wireless manner. The non-contact type wireless communication device can be configured by an antenna, a microcontroller that processes transmitted and received signals, and the like.

In a case where the wireless communication unit 33 is disposed inside the housing 13, when a portion of the housing 13 that is located in a position corresponding to the wireless communication unit 33 is formed from metal, it is difficult to perform wireless communication between the wireless communication unit 33 and a counterpart wireless communication unit 41 although the counterpart wireless communication unit 41 approaches the wireless communication unit 33. The reason is that electric waves are blocked in a case where a metal plate is placed between the wireless communication unit 33 and the counterpart wireless communication unit 41. Accordingly, conventionally, in a case where the wireless communication unit 33 is disposed inside the housing 13, the periphery of a portion, which corresponds to the position of the wireless communication unit 33, of the housing 13 needs to be formed from a non metallic material such as plastic.

However, when the portion of the housing 13 that is located in the position corresponding to the wireless communication unit 33 is formed from a non-metallic material, the outer appearance of the notebook PC 10 is spoiled. In addition, in order to acquire the impact strength equivalent to that of a metallic material by using a non metallic material, the thickness of the portion of the housing 13 that is located in a position corresponding to the wireless communication unit 33 and is formed from a non-metallic material needs greatly increased. In addition, a non-metallic member cannot be easily used in a portion of the housing 13 such as a portion in which the keyboard 14 is disposed or the like. Thus, when a method in which a non-metallic member is used in a portion of the housing 13 is used, the range in which the wireless communication unit 33 can be built is limited.

Accordingly, the notebook PC 10 according to this embodiment is configured such that the portion of the housing 13 that corresponds to the wireless communication unit 33 is formed to be freely opened or closed.

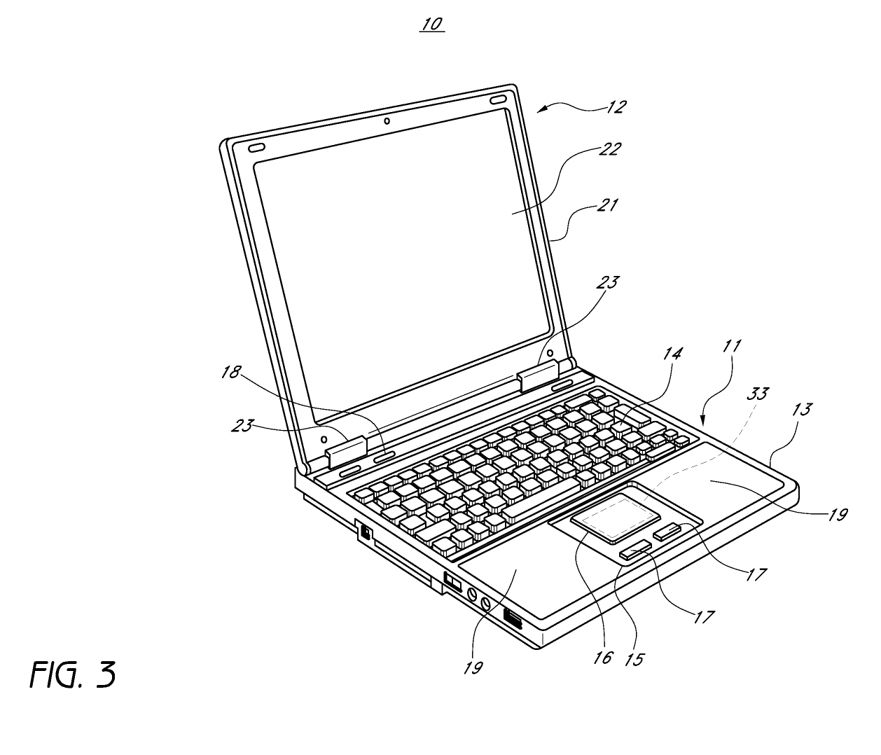

FIG. 3 is an external view showing an example of the notebook PC 10 in which the wireless communication unit 33 is disposed on the lower side of the touchpad unit 15.

As shown in FIG. 3, in a case where the wireless communication unit 33 is disposed on the lower side of the touch pad unit 15, when the touch pad unit 15 is formed by a metallic member or the inside of the touchpad unit 15 is covered with a metallic member, the wireless communication unit 33 and the counterpart wireless communication unit 41 cannot communicate with each other in a wireless manner even in a case where the counterpart wireless communication unit 41 approaches the wireless communication unit 33.

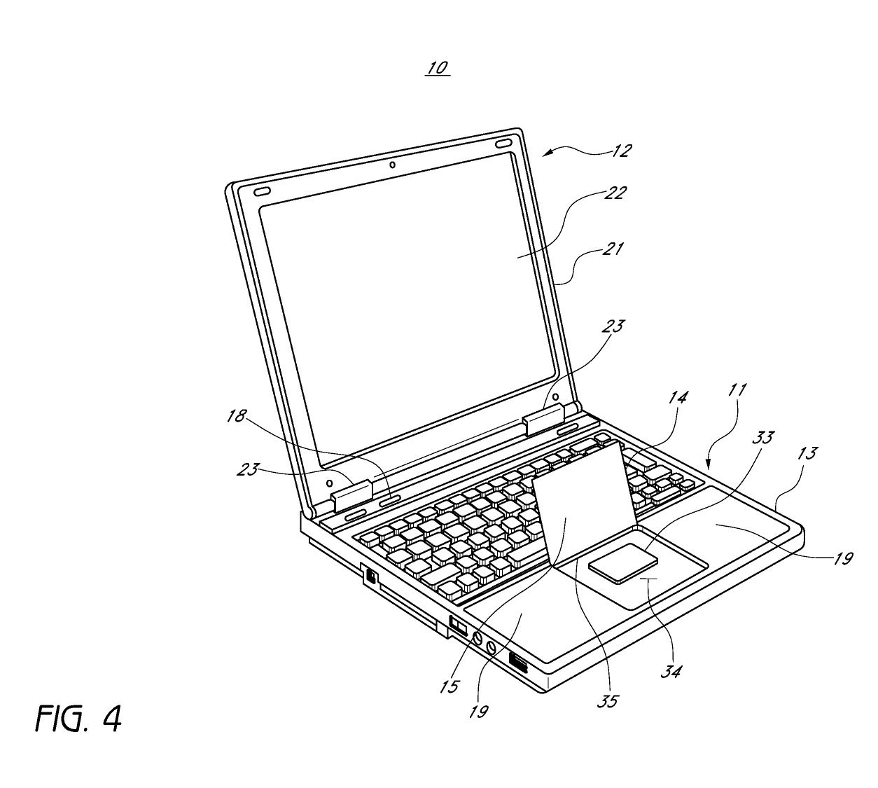

FIG. 4 is an explanatory diagram showing an example of the appearance of the exposed wireless communication unit 33 by opening the touchpad unit 15.

As shown in FIG. 4, in the housing 13, an opening 34 is disposed so as to expose the wireless communication unit 33. The touchpad unit 15 also serves as a lid member that allows the opening of the opening 34 to be freely opened or closed. In FIG. 4, an example of a case where the touch pad unit 15 is connected to the housing 13 by a hinge 35 such that the opening can be freely opened or closed is shown. However, the touchpad unit 15 (lid member) may be configured to be freely able to be attached to or detached from the housing 13. In addition, not the entire touchpad unit 15 but only the pad 16 may be configured to serve as the lid member.

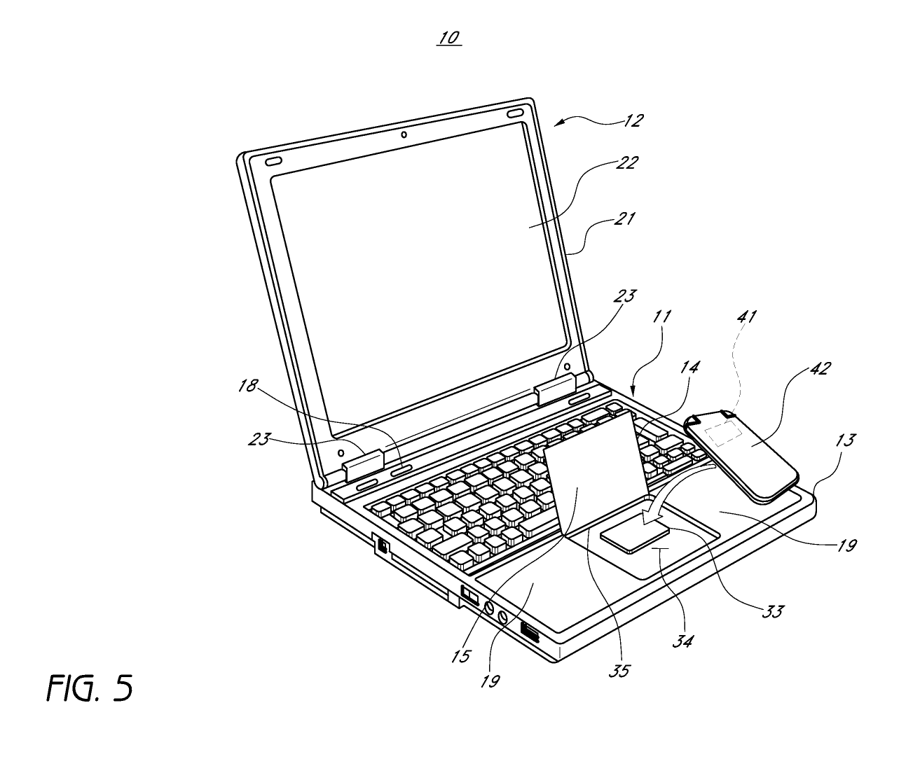

FIG. 5 is an explanatory diagram showing an example of the appearance of approaching of the counterpart wireless communication unit 41 to the exposed wireless communication unit 33 so as to be able to communicate with each other. FIG. 5 represents an example of a case where a cellular phone 42 having the counterpart wireless communication unit 41 approaches the wireless communication unit 33.

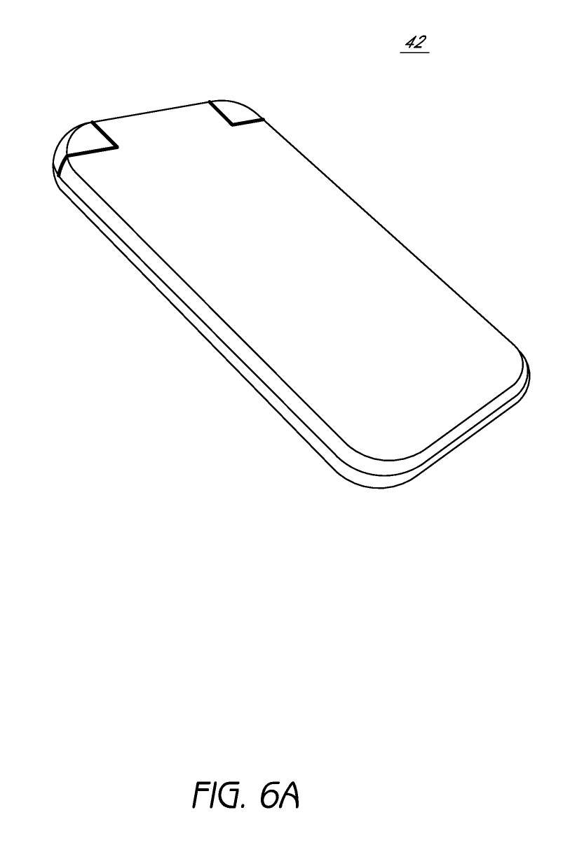

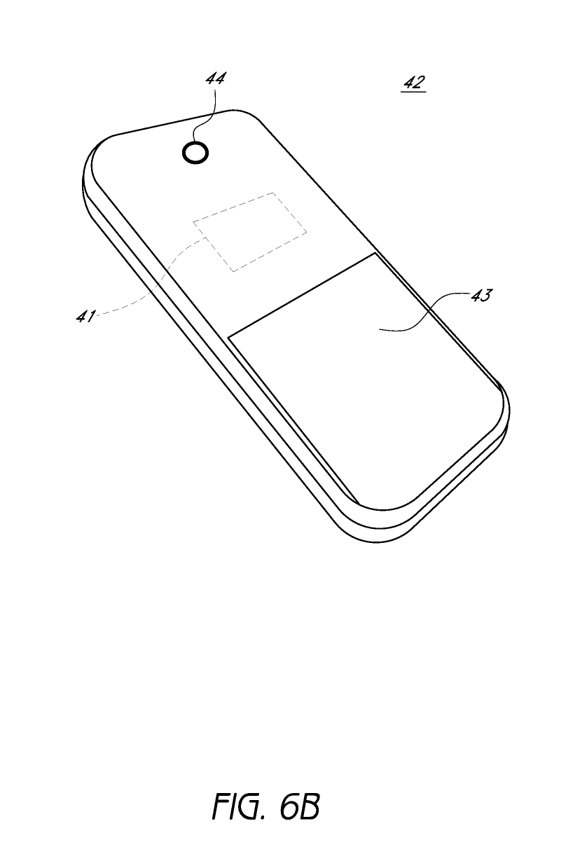

FIG. 6 is a perspective view showing the external appearance of a cellular phone 42 that has a counterpart wireless communication unit 41. FIG. 6A is a front perspective view of the cellular phone 42, and FIG. 6B is a perspective view showing the inside thereof. As shown in FIG. 6B, the counterpart wireless communication unit 41 is disposed between a secondary cell 43 and a camera 44 on the rear side of the cellular phone 42. In addition, a portion of the housing of the cellular phone 42 that corresponds to the counterpart wireless communication unit 41 is formed from a non-metallic material such as plastic so as not to obstruct wireless communication.

When the counterpart wireless communication unit 41 approaches the exposed wireless communication unit 33 as shown in FIG. 5, the counterpart wireless communication unit 41 and the wireless communication unit 33 can communicate with each other in a wireless manner.

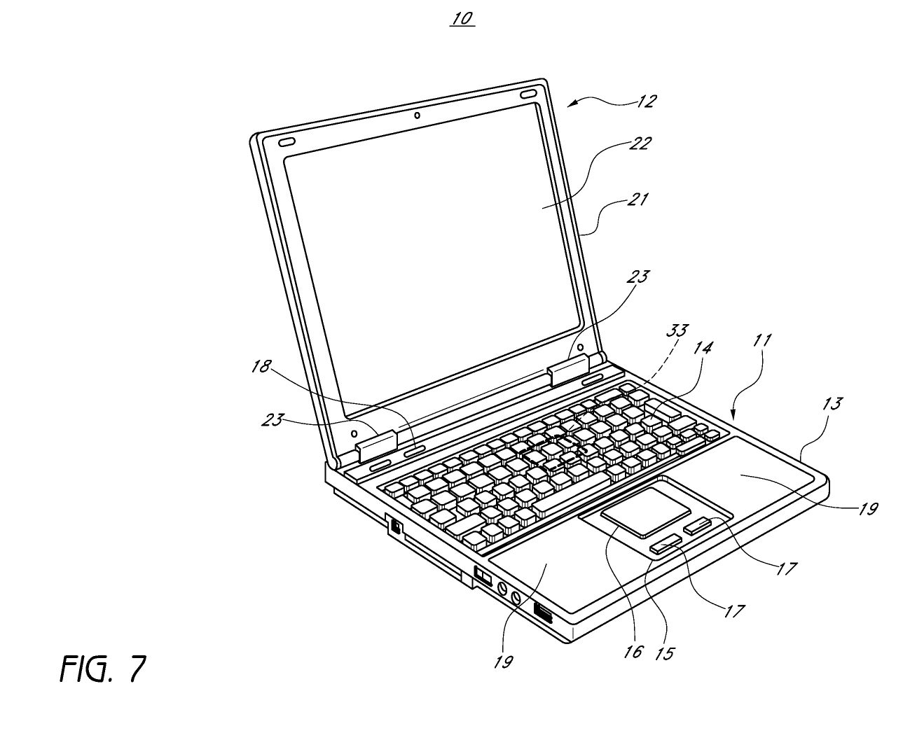

Subsequently, modified examples of the installation position of the wireless communication unit 33 will be described with reference to FIGS. 7 to 10.

FIG. 7 is an external view showing an example of the notebook PC 10 in which the wireless communication unit 33 is disposed on the lower side of the keyboard 14.

Generally, the rear face of the keyboard 14 is covered with a metallic member. Accordingly, in a case where the wireless communication unit 33 is disposed on the lower side of the keyboard 14, even when the counterpart wireless communication unit 41 approaches the wireless communication unit 33, the counterpart wireless communication unit 41 and the wireless communication unit 33 cannot communicate with each other.

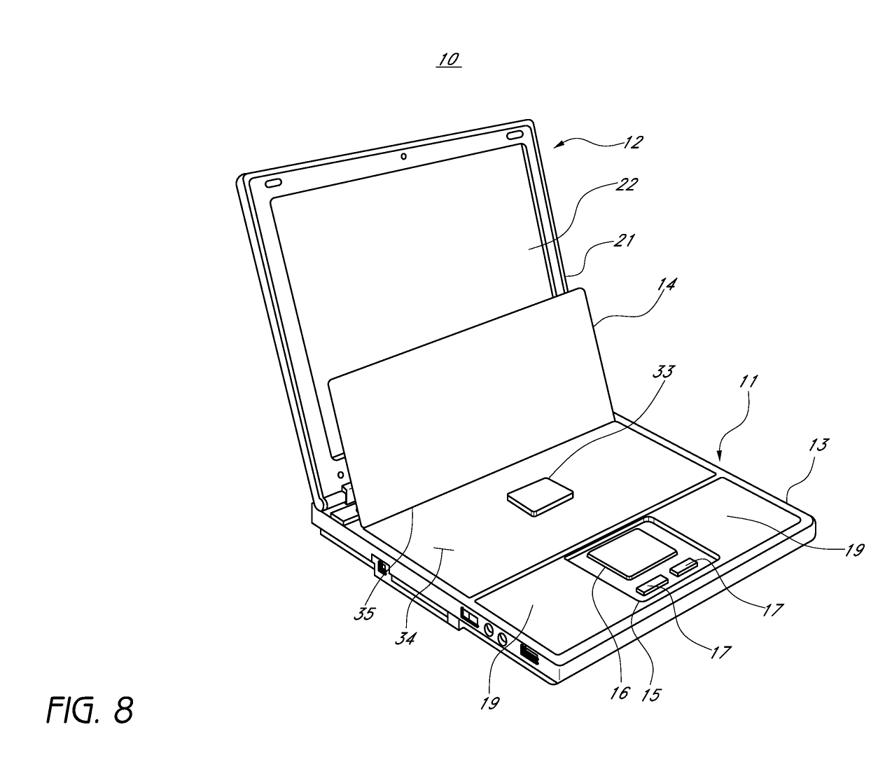

FIG. 8 is an explanatory diagram showing an example of the appearance of exposure of the wireless communication unit 33 by opening the keyboard 14.

As shown in FIG. 8, it may be configured that an opening 34 is disposed in a portion of the housing 13 that corresponds to the wireless communication unit 33, and the keyboard 14 serves as a lid member that can freely open or close the opening of the opening 34. In FIG. 8, an example of a case where the keyboard 14 is connected to the housing 13 by the hinge 35 so as to freely open or close the opening is shown. Here, the keyboard 14 (lid member) may be configured to be freely attached to or detached from the housing 13.

In addition, in FIG. 8, an example of the case where the opening 34 is disposed in a portion of the housing 13 that corresponds to the entire keyboard 14 is shown. However, the opening 34 only needs to be disposed so as to expose the wireless communication unit 33, and accordingly, the opening 34 of the housing 13 and the keyboard 14 may be configured such that only a portion of the keyboard 14 serves as the lid member.

In the same manner as in the example represented in FIG. 5, when a counterpart wireless communication unit 41 approaches the exposed wireless communication unit 33, the counterpart wireless communication unit 41 and the wireless communication unit 33 can communicate with each other in a wireless manner.

The information processing apparatus according this embodiment includes the housing 13 that is formed by a metallic member. In addition, in the information processing apparatus according to this embodiment, the wireless communication unit 33 is disposed inside the housing 13, the opening 34 is disposed such that the wireless communication unit 33 is exposed in the portion of the housing 13 that corresponds to the wireless communication unit 33, and the wireless communication portion 33 is exposed by opening the lid member (the keyboard 14 or the touchpad unit 15) that can freely open or close the opening of the opening 34. As a result, the wireless communication unit 33 disposed on the lower side of the keyboard 14 that is formed by a metal member or the lower side of the touchpad unit 15 can be arbitrarily exposed.

Therefore, according to the information processing apparatus of this embodiment, the range in which the wireless communication unit 33 can be built inside the housing 13 can be increased, and the wireless communication unit 33 disposed inside the housing 13 can be easily used by opening or closing the lid member (the keyboard 14 or the touchpad portion 15). In addition, in a case where a member cut out from the housing 13 is used as the lid member for disposing the opening 34, the appearance at the time of non-use can be maintained.

The notebook PC 10 may be configured that a slide mechanism is disposed in the lid member, and the opening 34 is opened by sliding the lid member in parallel with the surface of the housing 13. The opening 34 may be disposed on the side face or the lower side of the housing 13 or in the housing 21 as long as it is disposed in a position corresponding to the position in which the wireless communication unit 33 is disposed.

In addition, the present invention can be applied to various information processing apparatuses each having a housing formed by a metallic member other than the notebook PC 10 described in the embodiment as above. In particular, the present invention is appropriate to a mobile-type information processing apparatus such as a PDA (Personal Digital Assistant), a mobile-type game device, a mobile-type music player, or a mobile-type motion picture reproducing device.

Although the embodiment according to the present invention has been described above, the present invention is not limited to the above-mentioned embodiment but can be variously modified.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. An information processing apparatus comprising:
a wireless communication module configured to wirelessly communicate with counterpart devices;
a housing configured to contain the wireless communication module, the housing comprising an opening for exposing the wireless communication module;
a lid configured to move between an open position where the opening is open and a closed position where the opening is closed; and
an input device on the housing, configured to receive an input and to generate an operation signal in accordance with the input,
wherein the input device comprises the lid.

2. The apparatus of claim 1,
wherein the input device is electrically connected to components in a main body of the apparatus in order to output the operation signal to the components when the lid is either in the open position and the closed position.

3. The apparatus of claim 2 further comprising:
a hinge configured to connect the lid to the housing and to move between the open position and the closed position.

4. The apparatus of claim 2,
wherein the input device comprises a touchpad or a keyboard.

5. The apparatus of claim 4,
wherein the lid is either on the touchpad or on the keyboard.
